(19) United States
(12) Patent Application Publication
(10) Pub. No.: US 2018/0218992 A1
(43) Pub. Date: Aug. 2, 2018

(54) Semiconductor Device, Method for Fabricating a Semiconductor Device and Method for Reinforcing a Die in a Semiconductor Device

(71) Applicant: Infineon Technologies AG, Neubiberg (DE)

(72) Inventors: Valerie Vivares, Munich (DE); Edward Myers, Munich (DE)

(21) Appl. No.: 15/886,634

(22) Filed: Feb. 1, 2018

(30) Foreign Application Priority Data
Feb. 2, 2017 (DE) 102017102035.7

(51) Int. Cl. H01L 23/00; H01L 23/31; H01L 21/3105; H01L 21/321; H01L 21/304

(52) U.S. Cl. CPC H01L 24/13; H01L 23/3157; H01L 21/31053; H01L 21/32115; H01L 21/304; H01L 2224/13193; H01L 2224/1146; H01L 2224/13111; H01L 2224/13139; H01L 2224/16104; H01L 2224/13564; H01L 2224/1357; H01L 2224/13147

(57) ABSTRACT

A semiconductor device includes a semiconductor die having a first main face, a second main face and side faces connecting the first main face and the second main face. The semiconductor device also includes a conductive column arranged on the first main face of the semiconductor die and electrically coupled to the semiconductor die, and an insulating body arranged on the first main face of the semiconductor die. The insulating body has an upper main face and side faces. The upper main surface of the insulating body is coplanar with a top face of the conductive pillar. The semiconductor device further includes a metal layer arranged on the top face of the conductive pillar. The side faces of the semiconductor die and the side faces of the insulating body are coplanar.

### TECHNICAL FIELD

This disclosure relates to a semiconductor device, a method for fabricating a semiconductor device and a method for reinforcing a die in a semiconductor device.

### BACKGROUND

Semiconductor device manufacturers constantly strive to improve the performance of their products, for example to reduce electrical resistance or improve heat dissipation properties. Improving the performance may comprise reducing the size of semiconductor devices like for example semiconductor dies. This may in turn give rise to handling problems because smaller products may be less durable. Furthermore, it may be more difficult to electrically connect smaller semiconductor devices to e.g. a circuit board. It may be desirable to combine improved performance with good durability and easy handling of the semiconductor device.

### SUMMARY

Various aspects pertain to a semiconductor device, the semiconductor device comprising: a die comprising a first main face, a second main face and side faces connecting the first main face and the second main face, at least one conductive column arranged on the first main face of the die and electrically coupled to the die and an insulating body arranged on the first main face of the die, the insulating body comprising an upper main face and side faces, wherein the at least one conductive column is exposed on the upper main face of the insulating body and wherein the side faces of the die and the side faces of the insulating body are coplanar.

Various aspects pertain to a method of fabricating a semiconductor device, the method comprising: providing a die comprising a first main face, a second main face and side faces connecting the first main face and the second main face, arranging at least one conductive column on the first main face of the die and electrically coupling the at least one conductive column to the die and arranging an insulating body on the first main face of the die, the insulating body comprising an upper main face and side faces, wherein the side faces of the die and the side faces of the insulating body are coplanar.

Various aspects pertain to a method of reinforcing a die in a semiconductor device using an insulating body, wherein the die comprises a first main face, a second main face and side faces connecting the first main face and the second main face, wherein at least one conductive column is arranged on the first main face of the die and is electrically coupled to the die, wherein the insulating body comprises an upper main face and side faces, wherein the at least one conductive column is exposed on the upper main face of the insulating body and wherein the side faces of the die and the side faces of the insulating body are coplanar.

Those skilled in the art will recognize additional features and advantages upon reading the following detailed description, and upon viewing the accompanying drawings.

### BRIEF DESCRIPTION OF THE DRAWINGS

The accompanying drawings illustrate examples and together with the description serve to explain principles of the disclosure. Other examples and many of the intended advantages of the disclosure will be readily appreciated as they become better understood by reference to the following detailed description. The elements of the drawings are not necessarily to scale relative to each other. Like reference numerals designate corresponding similar parts.

FIG. 1 shows a schematic side view of a semiconductor device according to the disclosure.

FIG. 2 shows a schematic side view of an arrangement comprising a semiconductor device arranged on a substrate according to the disclosure.

FIGS. 3A-3I show schematic side views of a semiconductor device in various stages of fabrication according to an example of a method for fabricating a semiconductor device.

FIGS. 4A-4H show schematic side views of a semiconductor device in various stages of fabrication according to another example of a method for fabricating a semiconductor device.

FIG. 5 shows a flow diagram of a method for fabricating a semiconductor device according to the disclosure.

### DETAILED DESCRIPTION

While a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. Also, the term “exemplary” is merely meant as an example, rather than the best or optimal.

The semiconductor die(s) described further below may be of different types, may be manufactured by different technologies and may include for example integrated electrical, electro-optical or electro-mechanical circuits and/or passives, logic integrated circuits, control circuits, microprocessors, memory devices, etc. The semiconductor die(s) may comprise a horizontal transistor structure or a vertical transistor structure.

The semiconductor die(s) can be manufactured from specific semiconductor material, for example Si, SiC, SiGe, GaAs, GaN, or from any other semiconductor material. The semiconductor die(s) considered herein may be thin.

The semiconductor die may have contact pads (or electrodes) which allow electrical contact to be made with the integrated circuits included in the semiconductor die. The contact pads may be arranged all at only one main face of the semiconductor die or at both main faces of the semiconductor die. They may include one or more contact pads metal layers which are applied to the semiconductor material of the semiconductor die. The contact pads metal layers may be manufactured with any desired geometric shape and any desired material composition. For example, they may comprise or be made of a material selected of the group of Cu, Ni, NiSn, Au, Ag, Pt, Pd, an alloy of one or more of these metals, an electrically conducting organic material, or an electrically conducting semiconductor material.

The semiconductor die may be covered with an insulating body as described further below. The insulating body may be configured to reinforce the semiconductor die. The insulating body may be electrically insulating. The insulating body may comprise or be made of any appropriate mold compound or epoxy or plastic or polymer material such as, e.g., a duroplastic, thermoplastic or thermosetting material or laminate (prepreg), and may e.g. contain filler materials. Various techniques may be employed to cover the semiconductor die with the insulating body, for example molding or lamination. Heat and/or pressure may be used to apply the insulating body.

In the following a conductive column arranged on the semiconductor die is described. The conductive column may be electrically conductive and may comprise or consist of any suitable material. For example, the conductive column may comprise or consist of a metal like Cu, Sn or Ag. The conductive column may comprise or consist of a solder. The conductive column may comprise or consist of graphene. The conductive column may be fabricated using any suitable fabrication method. For example, a lithography process and a plating process may be used. According to another example, a soldering process may be used. An exemplary method of fabrication is described further below.

In several examples layers or layer stacks are applied to one another or materials are applied or deposited onto layers. It should be appreciated that any such terms as “applied” or “deposited” are meant to cover literally all kinds and techniques of applying layers onto each other. In particular, they are meant to cover techniques in which layers are applied at once as a whole like, for example, laminating techniques as well as techniques in which layers are deposited in a sequential manner like, for example, sputtering, plating, molding, CVD, 3D printing, etc.

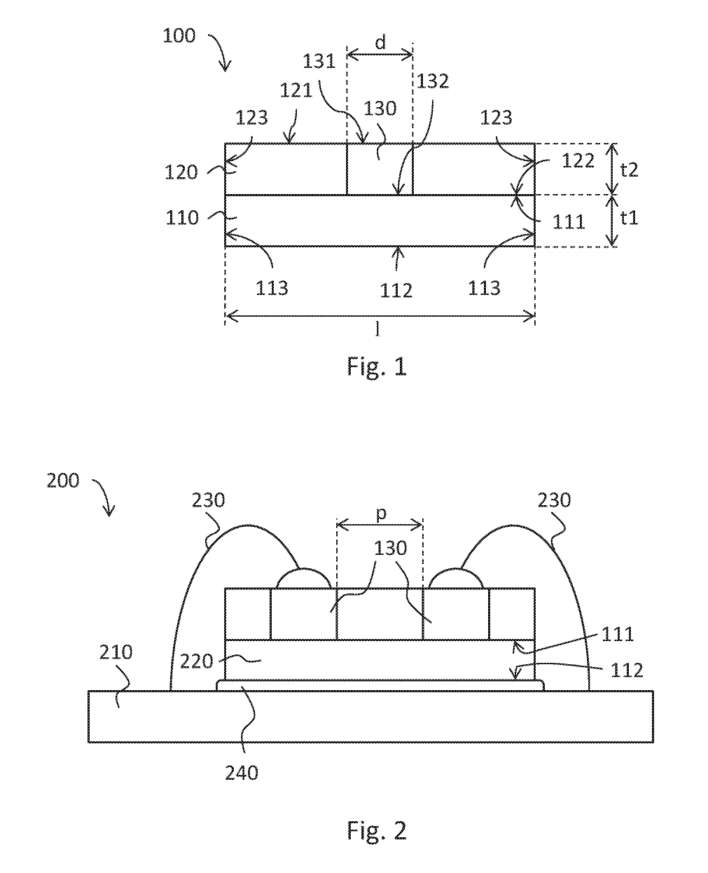

FIG. 1 shows an example of a semiconductor device 100 according to the disclosure. The semiconductor device 100 comprises a die or semiconductor die 110, an insulating body 120 and at least one conductive column 130. The die 110 comprises a first main face 111, a second main face 112 and side faces 113 connecting the first and second main face 111, 112. The insulating body comprises an upper main face 121, a lower main face 122 and side faces 123 connecting the upper and the lower main face 121, 122. The conductive column 130 comprises a top face 131 and a bottom face 132.

The first main face 111 of the die 110 and the lower main face 122 of the insulating body 120 may be coplanar. The bottom face of the conductive column 130 and one or more of the first main face 111 and the lower main face 122 may be coplanar. The upper main face 121 of the insulating body 120 and the top face 131 of the conductive column 130 may be coplanar. The side faces 113 of the die and the side faces 123 of the insulating body 120 may be coplanar.

The semiconductor device 100 may have any suitable length 1, for example a length 1 of about 2 mm, about 4 mm, about 6 mm, about 8 mm, about 1 cm, about 1.5 cm, about 2 cm or more than 2 cm. The die 110 may have any suitable thickness t1, for example a thickness t1 of less than or about 20 μm, less than or about 30 μm, less than or about 40 μm, less than or about 50 μm, less than or about 60 μm or more than 60 μm. A die with a thickness t1 of no more than 60 μm may be termed a “thin” die. However, the die 110 may also be a “thick” die, meaning a die with a thickness of more than 60 μm, for example more than or about 100 μm, more than or about 150 μm, more than or about 200 μm, more than or about 400 μm, more than or about 600 μm, more than or about 725 μm, more than or about 800 μm or more than 800 μm. The insulating body 120 (and the conductive column 130) may have any suitable thickness, for example a thickness t2 of less than or about 30 μm, less than or about 60 μm, less than or about 75 μm, less than or about 90 μm, less than or about 120 μm, less than or about 150 μm, less than or about 180 μm or more than 180 μm. The conductive column 130 may have any suitable diameter d, for example a diameter d of less than or about 50 μm, less than or about 80 μm, less than or about 100 μm, less than or about 120 μm, less than or about 150 μm, or more than 150 μm.

The conductive column 130 may have any suitable shape. For example, the conductive column 130 as seen from the top may be round, quadratic or rectangular.

The semiconductor device 100 may further comprise a backside metallization layer arranged on the second main face 112 of the die 110 (not shown in FIG. 1). The backside metallization layer may be a backside metallization of the die 110. The backside metallization layer may comprise any suitable metal or metals and may comprise one single layer or several layers. The backside metallization layer may for example comprise one or more metal layers with an Au or Ag finish.

The backside metallization layer may also comprise an oxidation prevention layer. The backside metallization layer may have any suitable thickness and may be thin compared to thickness t1 or t2. For example, the backside metallization layer may have a thickness of less than 5 μm, less than 1 μm, or less than 600 nm.

The semiconductor device 100 may further comprise an additional layer arranged on the top face 131 of the conductive column 130 (not shown in FIG. 1). The additional layer may be arranged solely on the top face 131 or it may be arranged both on the top face 131 of the column 130 and on the upper main face 121 of the insulating body 120. The additional layer may be thinner than 500 nm, thinner than 300 nm, thinner than 200 nm, or thinner than 100 nm.

The additional layer may be configured to act as an oxidation prevention layer preventing oxidation of the conductive column 130. The additional layer may be configured to act as an adhesion promotion layer allowing an electrical connection element like a clip or a wire bond to be coupled (e.g. soldered) to the top face 131 of the conductive column 130. According to an example, the additional layer may be a solder layer. The additional layer may be a metal layer. The additional layer may comprise a single metal layer or more than one metal layer.

The die 110 may comprise at least one contact pad on its first main face 111 (not shown in FIG. 1). The at least one contact pad may be arranged below the bottom face 132 of the conductive column 130 and may be electrically coupled to the conductive column 130. Therefore, the conductive column 130 may act as an electrical connector for the contact pad. According to an example, a conductive column 130 is arranged on every contact pad on the first main face 111 of the die.

According to an example of the semiconductor device 100, the insulating body 120 and the one or more conductive columns 130 are not arranged over the first main face 111 but over the second main face 112 and may in particular be arranged over a backside metallization layer. The conductive column(s) 130 may be electrically coupled to the backside metallization layer. Therefore, according to this example of the semiconductor device 100, the first main face 111 comprising contact pads is exposed and the second main face 112 optionally comprising a backside metallization layer is covered by the insulating body 120 and the conductive column(s) 130.

According to yet another example of the semiconductor device 100, the first main face 111 is covered by a first insulating body and one or more first conductive columns and the second main face 112 is covered by a second insulating body and one or more second conductive columns.

Due to the presence of the insulating body 120 and due to the conductive column 130 acting as a connector for an electrode on the first main face 111 of the die the semiconductor device 100 may basically be handled like a bare die with a thickness of t1+t2, meaning that the same processes for attaching the semiconductor device 100 to a board and for electrically coupling the semiconductor device 100 to the board can be used as those that are used for a bare die with a thickness of t1+t2. However, due to the smaller thickness of the die 110 the electrical properties of the die 110 (and therefore the semiconductor device 100) may be better (e.g. lower electrical resistance) than those of a bare die with a thickness of t1+t2. At the same time the insulating body reinforces the thin die 110 such that it exhibits comparable durability as a thick bare die (a die with a thickness of t1+t2). Therefore, the semiconductor device 100 combines the improved electrical performance of a thin die with the ease of use of a thick die.

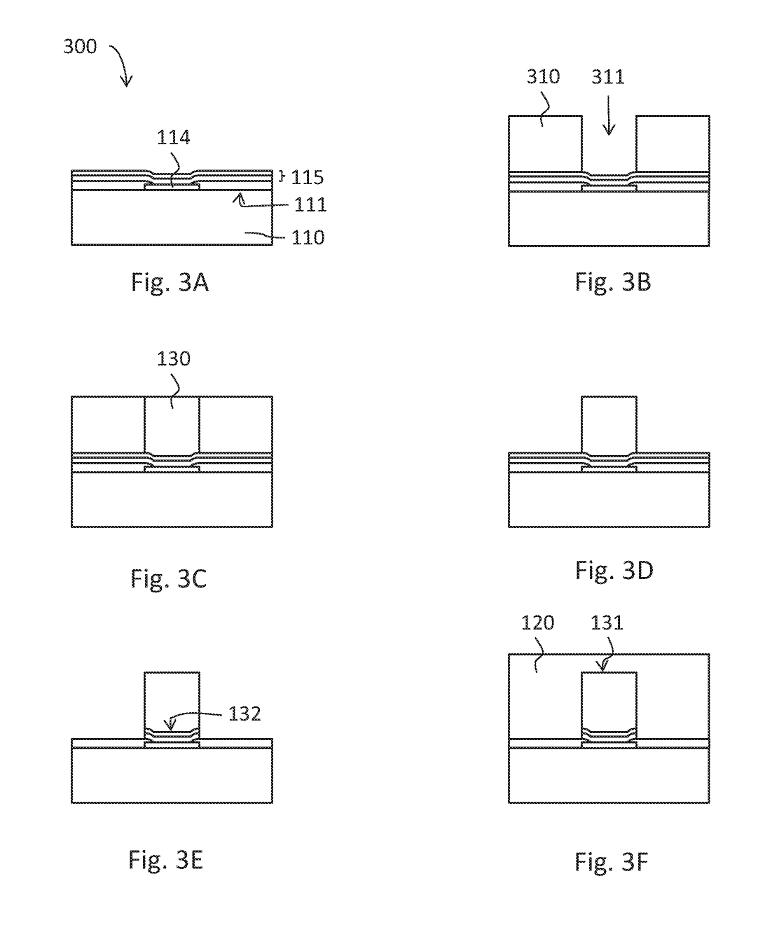

FIG. 2 shows an arrangement 200 comprising a substrate 210 and a semiconductor device 220 arranged on the substrate 210 and electrically connected to the substrate 210 by connectors 230, wherein the connectors 230 are attached to the conductive columns 130, in particular to the top face 131 of the conductive columns 130. The semiconductor device 220 may be an example of a semiconductor device 100 and reiteration of features is avoided for the sake of brevity.

The connectors 230 shown in FIG. 2 are bonding wires, however, any other suitable connectors may be used, for example clips.

The conductive columns 130 may be spaced apart with any suitable pitch p, for example a pitch p of about 200 μm. The pitch p may correspond to the distance between contact pads on the first main face 111 of the die 110, wherein the conductive columns 130 are arranged on the contact pads.

The semiconductor device 220 may be mounted on the substrate 210 using an adhesive layer 240 arranged between the second main face 112 of the die 110 and the substrate 210. The adhesive layer 240 may for example comprise a glue or a solder and may be configured to allow heat produced in the die 110 to efficiently dissipate through the adhesive layer 240 into the substrate 210.

According to an example, the arrangement 200 comprises an encapsulation body encapsulating the semiconductor device 220 (not shown in FIG. 2). The encapsulation body may also encapsulate the connectors 230. The encapsulation body may be formed after the semiconductor device 220 has been attached to the substrate 210 and after the semiconductor device 220 has been electrically connected to the substrate 210 using the connectors 230. The encapsulation body may for example comprise or consist of a mold or a laminate.

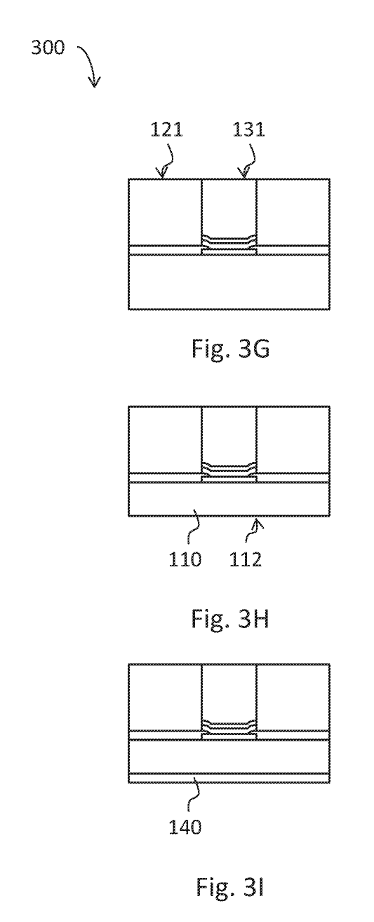

In the following with respect to FIGS. 3A-3I an example of a method 300 according to the disclosure for fabricating a semiconductor device like the semiconductor device 100 is shown.

FIG. 3A shows a die 110 comprising contact pads 114 on the first main face 111 of the die 110. One or more metallization layers 115 are fabricated on the first main face 111. The one or more metallization layers 115 may be an under bump metallization (UBM).

Afterwards a photolithography process may be performed (FIG. 3B). For example, a photoresist layer is provided above the one or more metallization layers 115. The photoresist layer is exposed using a suitable photo mask and subsequently developed in order to fabricate a photoresist structure 310 comprising a hole 311 in a place where a conductive column is to be fabricated.

FIG. 3C shows a conductive column 130 fabricated in the hole 311 of FIG. 3B. Fabricating the conductive column 130 may comprise a plating process, for example Cu plating.

FIG. 3D shows the die 110 and the conductive column 130 after removal of the photoresist structure 310.

Afterwards (FIG. 3E) an appropriate etching process may be used to etch the one or more metallization layers 115 such that the one or more metallization layers 115 only remain below the bottom face 132 of the conductive column 130.

FIG. 3F shows the fabrication of the insulating body 120 which may for example be applied onto the first main face 111 of the die using a molding process or a lamination process. As shown in FIG. 3F, the insulating body 120 may initially cover the top face 131 of the conductive column 130. However, the insulating body 120 may also be fabricated in such a manner that it does not cover the top face 131 of the conductive column 130.

As shown in FIG. 3G a removal process may be used to remove one or more of excess insulating body material and excess conductive column material. The removal process may comprise a planarization process or grinding process at the upper main face 121 of the insulating body 120 and the top face 131 of the conductive column 130. The surface comprising the upper main face 121 and the top face 131 may also be called the front side of the semiconductor device.

The die 110 may be thinned, for example using a backside grinding process at the second main face 112 of the die as shown in FIG. 3H. After thinning the die 110 may have a thickness t1 as described with respect to FIG. 1. Before thinning the die may have any suitable thickness, for example a thickness of a standard wafer. Before thinning the die may for example have a thickness of about 725 μm.

FIG. 3I shows that optionally a backside metallization layer 140 may be fabricated on the second main face 112 of the die. Application of the backside metallization layer 140 may for example comprise a physical vapor deposition (PVD) process.

Method 300 may further comprise forming an additional layer on the top face 131 of the conductive column 130. The additional layer may be formed after the removal process described with respect to FIG. 3G has been performed, but for example before the process shown in FIG. 3H is performed or before the process shown in FIG. 3I is performed or after the process shown in FIG. 3I is performed.

According to an example, the individual process steps of method 300 may be performed chronologically in the order shown in FIG. 3A-3I. According to another example, some process steps may be performed earlier or later than shown with respect to FIG. 3A-3I. For example, the thinning process step shown with respect to FIG. 3H may be performed earlier, for example as a first process step of method 300.

According to an example, the method 300 is a batch method that is performed on a whole wafer instead of on a singulated die 110. In other words, the die 110 may not have been singulated prior to performing method 300 but may still be a part of the wafer and the method 300 is performed on a part or all of the dies 110 of the wafer. According to another example, some or all of the steps of method 300 are performed on a singulated die 110.

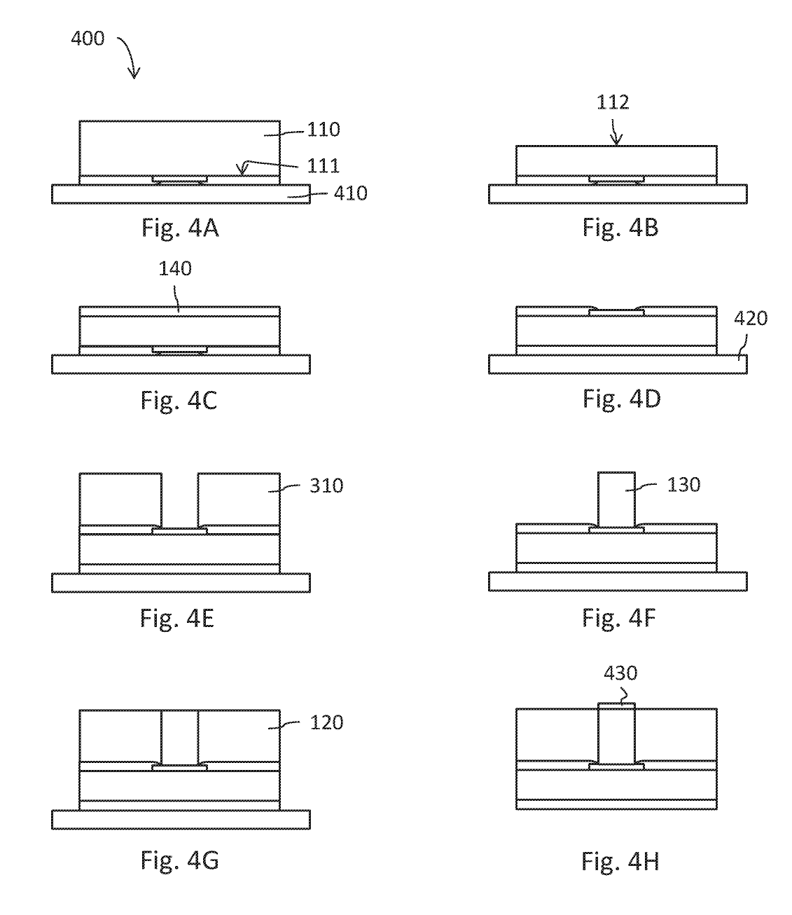

With respect to FIG. 4A-4H a further exemplary method 400 for fabricating a semiconductor device like the semiconductor device 100 is shown. Method 400 may correspond to method 300 and may comprise identical or similar process steps.

FIG. 4A: a die 110 is provided and is arranged on a first temporary carrier 410 with the first main face 111 of the die facing the first temporary carrier. The first temporary carrier 410 may comprise an adhesive tape and the die 110 may be attached to the adhesive tape. According to an example, the die 110 may also be a whole wafer and the method 400 may be a batch method that is performed on the whole wafer.

FIG. 4B: a thinning process like a backside grinding process may be performed on the second main face 112 of the die. Before thinning the die 110 may for example have a thickness t1 of about 725 μm and after thinning the die 110 may have a thickness t1 of about 60 μm.

FIG. 4C: a backside metallization layer 140 may be fabricated on the second main face 112 of the die.

FIG. 4D: the die 110 may be arranged on (e.g. attached to) a second temporary carrier 420 (e.g. a second temporary carrier 420 comprising an adhesive foil) with the second main face 112 of the die facing the second temporary carrier 420 and the die 110 may (subsequently) be removed from the first temporary carrier 410.

FIG. 4E: a photolithography process may be used to fabricate a photoresist structure 310 on the first main face 111 of the die.

FIG. 4F: a conductive column 130 may be formed on the first main face 111 of the die, e.g. over a contact pads of the die 110. The photoresist structure 310 may be removed.

FIG. 4G: an insulating body 120 may be formed on the first main face 111 of the die. A planarization process may be used to remove excess material from the upper main face 121 of the insulating body and the top face 131 of the conductive column.

FIG. 4H: an additional layer 430 may be formed on the top face 131 of the conductive column. The semiconductor device 100 may be singulated. The semiconductor device 100 may be removed from the second temporary carrier 420.

According to an example, the process steps of method 400 may be performed in the chronological order shown in FIG. 4A-4H. According to another example, any other suitable chronological order of the process steps may be used.

According to an example, the thinning process described with respect to FIG. 4B and the process of fabricating the backside metallization layer 140 described with respect to FIG. 4C may be performed after formation of the insulating body described with respect to FIG. 4G has been carried out.

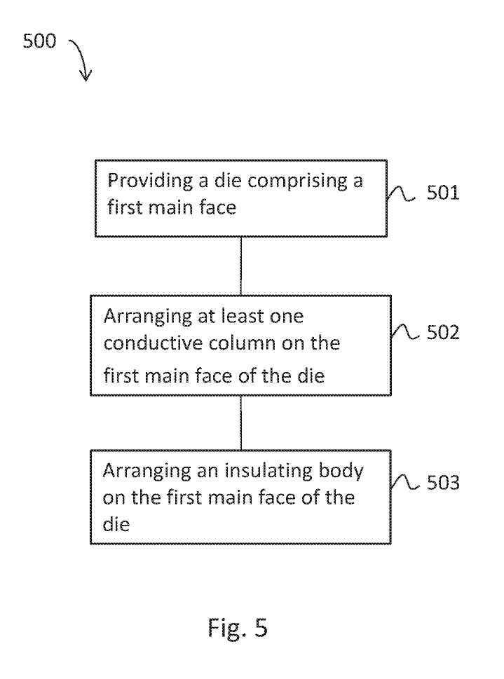

FIG. 5 shows a flow diagram of an exemplary method 500 for fabricating a semiconductor device like the semiconductor device 100. The method 500 may correspond to the method 300 or 400.

The method 500 comprises a first method step 501 of providing a die comprising a first main face, a second main face and side faces connecting the first main face and the second main face, a second method step 502 of arranging at least one conductive column on the first main face of the die and electrically coupling the at least one conductive column to the die and a third method step 503 of arranging an insulating body on the first main face of the die, the insulating body comprising an upper main face and side faces.

The method steps 501, 502 and 503 may be performed in the described order. The method 500 may comprise additional method steps, for example method steps described with respect to FIGS. 3A-3I and 4A-4H.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

As used herein, the terms “having”, “containing”, “including”, “comprising” and the like are open-ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

1. A semiconductor device, comprising:
a semiconductor die comprising a first main face, a second main face and side faces connecting the first main face and the second main face;
a conductive column arranged on the first main face of the semiconductor die and electrically coupled to the semiconductor die;
an insulating body arranged on the first main face of the semiconductor die and comprising an upper main face and side faces, the upper main surface of the insulating body being coplanar with a top face of the conductive pillar; and
a metal layer arranged on the top face of the conductive pillar,
wherein the side faces of the semiconductor die and the side faces of the insulating body are coplanar.

2. The semiconductor device of claim 1, wherein the conductive column comprises at least one of Cu, Sn, Ag and graphene.

3. The semiconductor device of claim 1, wherein the conductive column is electrically coupled to a contact pad of the semiconductor die.

4. The semiconductor device of claim 1, wherein the insulating body comprises at least one of a polymer, a mold compound, an epoxy, and filler materials.

5. The semiconductor device of claim 1, wherein the conductive column has a thickness of about 75 μm measured perpendicular to the first main face of the semiconductor die and a diameter of about 100 μm measured parallel to the first main face of the semiconductor die.

6. The semiconductor device of claim 1, wherein the insulating body has a thickness of about 75 μm measured perpendicular to the first main face of the semiconductor die.

7. The semiconductor device of claim 1, wherein the metal layer is thinner than 200 nm.

8. The semiconductor device of claim 1, further comprising a backside metallization layer arranged on the second main face of the semiconductor die.

9. The semiconductor device of claim 8, wherein the backside metallization layer comprises at least one of Au and Ag.

10. The semiconductor device of claim 1, wherein the metal layer is plated or deposited by CVD on the top face of the conductive pillar.

11. The semiconductor device of claim 1, wherein the metal layer is an oxidation prevention layer configured to prevent oxidation of the conductive pillar.

12. A method of fabricating a semiconductor device, the method comprising:
providing a semiconductor die comprising a first main face, a second main face and side faces connecting the first main face and the second main face;
plating a conductive column on the first main face of the semiconductor die, the conductive column being electrically coupled to the semiconductor die;
arranging an insulating body on the first main face of the semiconductor die, the insulating body comprising an upper main face and side faces, the upper main surface of the insulating body being coplanar with a top face of the conductive pillar; and
depositing a metal layer on the top face of the conductive pillar,
wherein the side faces of the semiconductor die and the side faces of the insulating body are coplanar.

13. The method of claim 12, further comprising:
planarizing the upper main face of the insulating body and the top face of the conductive column.

14. The method of claim 12, further comprising:
thinning the semiconductor die.

15. The method of claim 14, wherein thinning the semiconductor die comprises grinding the second main face of the semiconductor die.

16. The method of claim 12, further comprising:
forming a backside metallization layer on the second main face of the semiconductor die.

17. The method of claim 12, wherein the conductive column is plated on the first main face of the semiconductor die by a photolithography process and a plating process.

18. A method of reinforcing a semiconductor die in a semiconductor device using an insulating body, the semiconductor die comprising a first main face, a second main face and side faces connecting the first main face and the second main face, the insulating body comprising an upper main face and side faces, the side faces of the semiconductor die and the side faces of the insulating body being coplanar, the method comprising:
depositing a conductive column on the first main face of the semiconductor die by a plating process, the conductive column being electrically coupled to the semiconductor die, the conductive column having a top face that is coplanar with the upper main face of the insulating body;
exposing the conductive column on the upper main face of the insulating body; and
forming a metal layer on the top face of the conductive pillar.

19. The method of claim 18, wherein the metal layer is formed on the top face of the conductive pillar by a plating process or a CVD process.
